(19) United States
(12) Patent Application Publication
(10) Pub. No.: US 2014/0252420 A1
(43) Pub. Date: Sep. 11, 2014

(54) SEMICONDUCTOR DEVICES INCLUDING GATE ELECTRODES WITH MULTIPLE PROTRUSIONS CONFIGURED FOR CHARGE TRANSFER

(71) Applicant: Samsung Electronics Co., Ltd., Suwon-si (KR)

(72) Inventors: Shinwook Yi, Hwaseong-si (KR); Hyoungsoo Ko, Hwaseong-si (KR); Kyungho Lee, Suwon-si (KR); Youngwoo Jung, Yongin-si (KR); Heegeun Jeong, Suwon-si (KR)

(73) Assignee: Samsung Electronics Co., Ltd., Suwon-si (KR)

(21) Appl. No.: 14/138,434

(22) Filed: Dec. 23, 2013

(30) Foreign Application Priority Data
Mar. 11, 2013 (KR) 10-2013-0025713

(51) Int. Cl. H01L 27/148

(52) U.S. Cl. CPC H01L 27/14812
USPC 257/229

(57) ABSTRACT

An image sensor device can include device isolation regions in a substrate and a photoelectric conversion portion in the substrate that can be between the device isolation regions. A transfer gate of the image sensor device, can be located over, and be electrically coupled to, the photoelectric conversion portion. The transfer gate can include at least two protrusions, that are separated from the device isolation regions, and that protrude toward the photoelectric conversion portion.

### CROSS-REFERENCE TO RELATED APPLICATIONS

This U.S. non-provisional patent application claims priority under 35 U.S.C. §119 to Korean Patent Application No. 10-2013-0025713, filed on Mar. 11, 2013, in the Korean Intellectual Property Office, the entire contents of which are hereby incorporated by reference.

### BACKGROUND

Example embodiments of the inventive concept relate to a semiconductor device.

Image sensors are semiconductor devices capable of converting electric signals into optical images. Image sensors may be classified into various types, including charge coupled device (CCD) type and complementary metal oxide semiconductor (CMOS) type. A CMOS image sensor (CIS) includes pixels arranged in two dimensions. Each of the pixels includes a photodiode (PD), which can convert incident light into an electric signal.

### SUMMARY

According to example embodiments of the inventive concepts, a semiconductor device may include a substrate, and a gate electrode provided on the substrate with a gate insulating layer interposed therebetween. The gate electrode may include a first gate pattern disposed on the substrate and a plurality of second gate patterns connected to the first gate pattern and extended into the substrate.

In example embodiments, the device may further include a device isolation layer provided on the substrate to delimit an active region. The second gate patterns may be spaced apart from the device isolation layer.

In example embodiments, at least one of the second gate patterns may have a width varying depending on a distance from the first gate pattern. For example, the width of at least one of the second gate patterns may be greater at a level adjacent to the first gate pattern than at a level distant from the first gate pattern.

In example embodiments, each of the second gate patterns may have an inclined sidewall.

In example embodiments, the semiconductor device may be an image sensor circuit and the gate electrode can be a transfer gate in the image sensor circuit. The semiconductor device may further include a floating diffusion region provided in a portion of the substrate adjacent to a side of the gate electrode, and a photoelectric conversion portion provided in a lower portion of the substrate at another side of the gate electrode. Here, a portion of the substrate between the second gate patterns may be adjacent to the floating diffusion region.

In example embodiments, the photoelectric conversion portion may further include a first doped region provided adjacent to the gate electrode, and a second doped region provided below the first doped region to have the same conductivity type as the floating diffusion region. The second gate patterns may be overlapped with the second doped region, in plan view of the image sensor circuit. A distance between the second gate pattern and the second doped region may be less than about 100 μm.

In other embodiments, the device may further include a first doped region provided adjacent to one of the second gate patterns in the substrate, and a second doped region provided adjacent to another of the second gate patterns in the substrate.

According to example embodiments of the inventive concepts, a semiconductor device may include a substrate, and a gate electrode provided on the substrate with a gate insulating layer interposed therebetween. The gate electrode may include a first gate pattern disposed on the substrate and at least one second gate pattern connected to the first gate pattern and extended into the substrate, and the second gate pattern may have an uneven bottom surface protruding into the substrate.

In example embodiments, a top of a bottom surface of the second gate pattern may be located at a level that may be equivalent to or lower than a bottom surface of the first gate pattern.

In some embodiments according to the inventive concept, an image sensor device can include device isolation regions in a substrate and a photoelectric conversion portion in the substrate that can be between the device isolation regions. A transfer gate of the image sensor device, can be located over, and be electrically coupled to, the photoelectric conversion portion. The transfer gate can include at least two protrusions, that are separated from the device isolation regions, and that protrude toward the photoelectric conversion portion.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram of an image sensor according to example embodiments of the inventive concept.

FIG. 2A is a layout diagram of an image sensor according to example embodiments of the inventive concept.

FIGS. 2B and 2C are sectional views taken along lines A-A′ and B-B′, respectively, of FIG. 2A.

FIG. 2D is a perspective view illustrating the image sensor of FIG. 2A.

FIG. 3A is a graph showing potential vs. depth, when one second gate pattern is provided.

FIG. 3B is a graph showing potential vs. depth, when two second gate patterns are provided in some embodiments according to the inventive concept.

FIG. 4A is a layout diagram of an image sensor according to other example embodiments of the inventive concept.

FIGS. 4B and 4C are sectional views taken along lines C-C′ and D-D′, respectively, of FIG. 4A.

FIG. 5A is a layout diagram of an image sensor according to example embodiments of the inventive concept.

FIGS. 5B and 5C are sectional views taken along lines E-E′ and F-F′, respectively, of FIG. 5A.

FIGS. 6A and 6B are layout diagrams of image sensors according to example embodiments of the inventive concept.

FIG. 7 is a sectional view taken along line F-F′ of FIG. 5A illustrating alternative embodiments according to the inventive concept.

FIG. 8 is a sectional view of a semiconductor device according to example embodiments of the inventive concept.

FIG. 9 is a block diagram illustrating an electronic device having an image sensor, according to example embodiments of the inventive concept.

FIGS. 10 through 14 show examples of multimedia devices, to which image sensors according to example embodiments of the inventive concept can be applied.

### DETAILED DESCRIPTION OF EMBODIMENTS ACCORDING TO THE INVENTIVE CONCEPT

Example embodiments of the inventive concepts are described with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

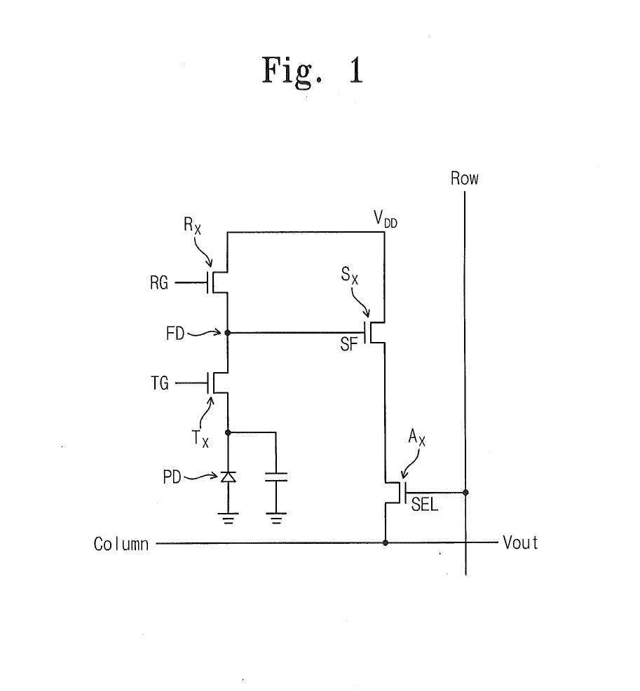

FIG. 1 is a circuit diagram of an image sensor according to example embodiments of the inventive concept.

Referring to FIG. 1, the image sensor may include a plurality of unit pixels, each of which includes a photoelectric conversion region PD, a transfer transistor Tx, a source follower transistor Sx, a reset transistor Rx, and a selection transistor Ax. The transfer transistor Tx, the source follower transistor Sx, the reset transistor Rx, and the selection transistor Ax may include a transfer gate TG, a source follower gate SF, a reset gate RG, and a selection gate SEL, respectively. A photoelectric conversion portion may be provided in the photoelectric conversion region PD. The photoelectric conversion portion may be a photodiode including an n-type impurity region and a p-type impurity region. The transfer transistor Tx may include a drain region serving as a floating diffusion region FD. The floating diffusion region FD may also serve as a source region of the reset transistor Rx. The floating diffusion region FD may be electrically connected to the source follower gate SF of the source follower transistor Sx. The source follower transistor Sx may be connected to the selection transistor Ax. The reset transistor Rx, the source follower transistor Sx, and the selection transistor Ax may be shared by adjacent pixels, and this makes it possible to increase an integration density of the image sensor.

Operations of the image sensor are described with reference to, for example, FIG. 1. When in a light-blocking state, a power voltage VDD may be applied to a drain region of the reset transistor Rx and a drain region of the source follower transistor Sx to discharge electric charges from the floating diffusion region FD. Thereafter, if the reset transistor Rx is turned-off and external light is incident into the photoelectric conversion region PD, electron-hole pairs may be generated in the photoelectric conversion region PD. Holes may be moved toward the p-type doped region, and electrons may be moved toward and accumulated in the n-type doped region. If the transfer transistor Tx is turned on, the electrons may be transferred to and accumulated in the floating diffusion region FD. A change in amount of the accumulated electrons may lead to a change in gate bias of the source follower transistor Sx, and this may lead to a change in source potential of the source follower transistor Sx. Accordingly, if the selection transistor Ax is turned on, an amount of the electrons may be read out as a signal to be transmitted through a column line.

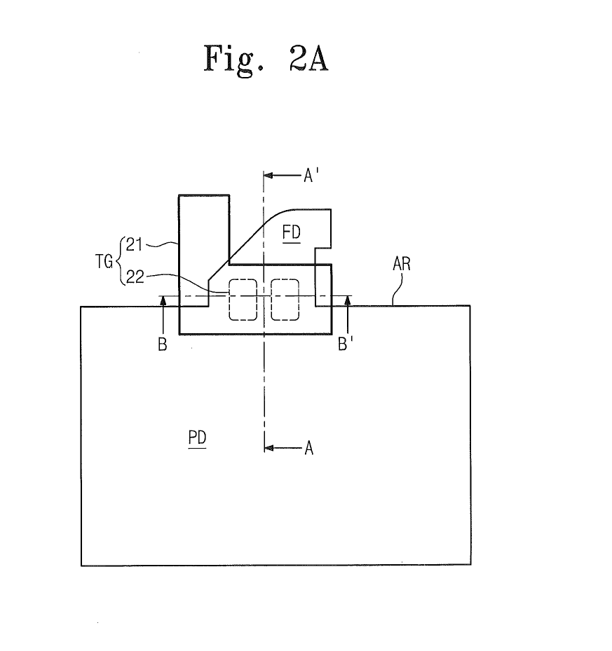

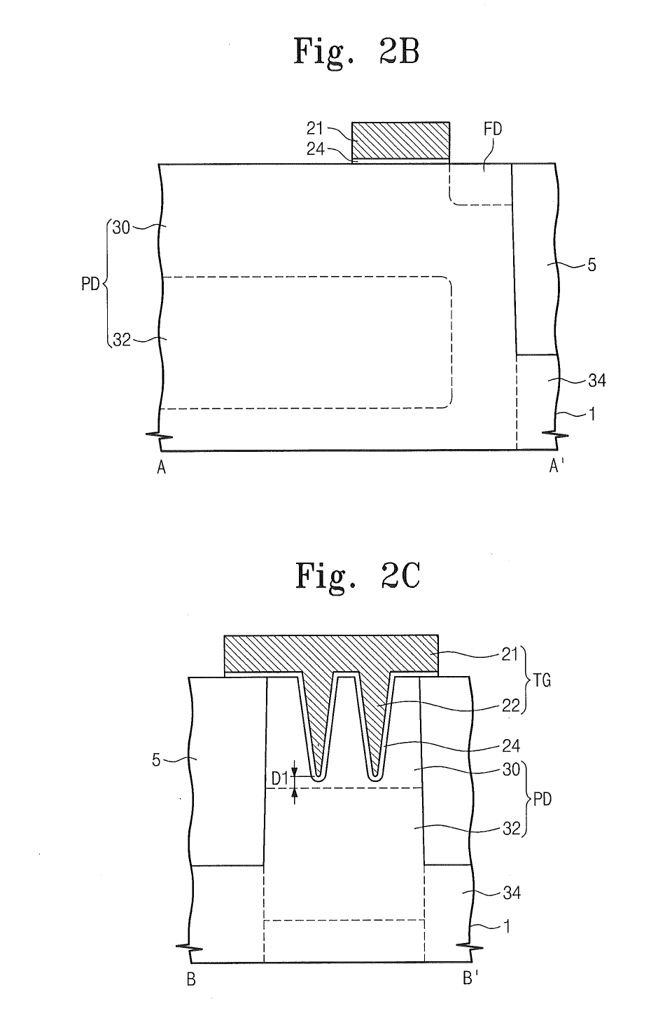

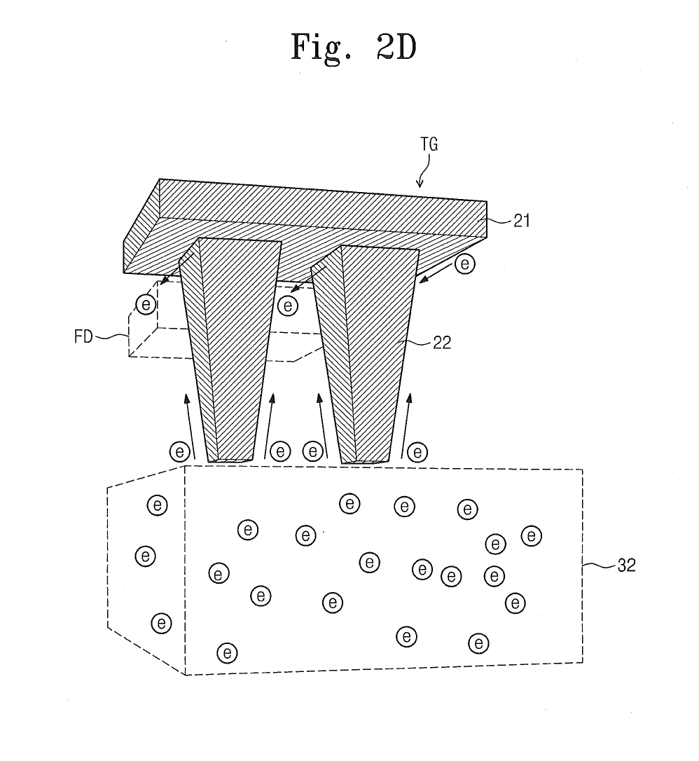

FIG. 2A is a layout diagram of an image sensor according to example embodiments of the inventive concept. FIGS. 2B and 2C are sectional views taken along lines A-A′ and B-B′, respectively, of FIG. 2A. FIG. 2D is a perspective view illustrating the image sensor of FIG. 2A.

Referring to FIGS. 2A through 2D, a device isolation layer 5 may be provided on a substrate 1 to define an active region AR. In plan view, the active region AR may include a rectangular unit pixel region and a protruding region extending from the unit pixel region. For example, as shown in FIG. 2A, the active region AR may include a rectangular unit pixel region and a protruding region extending from a side thereof. A first doped region 30 may be provided, for example, in the substrate 1. A second doped region 32 may be provided in the unit pixel region. The first doped region 30 may be doped with, for example, p-type impurities. The second doped region 32 may be doped with, for example, n-type impurities. The first doped region 30 and the second doped region 32 may provide the photoelectric conversion portion PD.

The device isolation layer 5 may be formed using a shallow trench isolation process. A channel stop region 34 may be provided below the device isolation layer 5. The channel stop region 34 may be doped to have the same conductivity type as the first doped region 30 and a higher doping concentration than the first doped region 30. The transfer gate TG may be disposed to cross a portion of the active region AR. The transfer gate TG may include a first gate pattern 21, which may be disposed on the substrate 1, and a plurality of second gate patterns 22, which may be connected to the first gate pattern 21 and extend (or protrude) into the substrate 1. Each of the second gate patterns 22 may be spaced apart from the device isolation layer 5. A width of the second gate pattern 22 may vary depending on a distance from the first gate pattern 21. For example, the width of the second gate pattern 22 may be greater at a higher level adjacent to the first gate pattern 21 than at a lower level distant from the first gate pattern 21. In other words, the second gate pattern 22 may be provided to have an inclined sidewall. In addition, due to the presence of the second gate patterns 22, the transfer gate TG may have an uneven bottom surface. In plan view, the second gate patterns 22 may be overlapped with the second doped region 32. In example embodiments, a distance D1 between the second gate pattern 22 and the second doped region 32 may be smaller than about 100 μm. A portion of the substrate 1 between the second gate patterns 22 may be adjacent to the floating diffusion region FD.

A gate insulating layer 24 may be interposed between the transfer gate TG and the substrate 1. The floating diffusion region FD may be provided in a top portion of the substrate 1 opposite to the unit pixel region and beside the transfer gate TG. The floating diffusion region FD may be doped to have the same conductivity type as the second doped region 32.

The substrate 1 may be covered with an interlayer insulating layer, and a plurality of interconnection lines allowing electric signals to be transmitted may be provided in the interlayer insulating layer. For example, an interconnection line may be electrically connected to the floating diffusion region FD. A color filter and/or a micro lens may be provided on a bottom or top surface of the substrate 1.

Operations of the image sensor according to the present embodiment are described with reference to, for example, FIG. 2D. Electrons (e) to be generated in the photoelectric conversion portion PD may be accumulated in the second doped region 32 (e.g., of n-type). If a voltage of applied to the transfer gate TG, the electrons (e) may start to be moved along sidewalls of the second gate patterns 22. Here, since the distance between the second gate patterns 22 and the second doped region 32 is very small (e.g., less than 100 μm), it is possible to move the electrons at higher speed. Further, the inclined sidewall of the second gate patterns 22 makes it possible to form a potential gradient. Accordingly, the electrons may be quickly moved toward the bottom surface of the first gate pattern 21 through a drift, but not diffusion, process, and then, be moved to the floating diffusion region FD along a portion of the substrate 1 adjacent to the bottom surface of the first gate pattern 21.

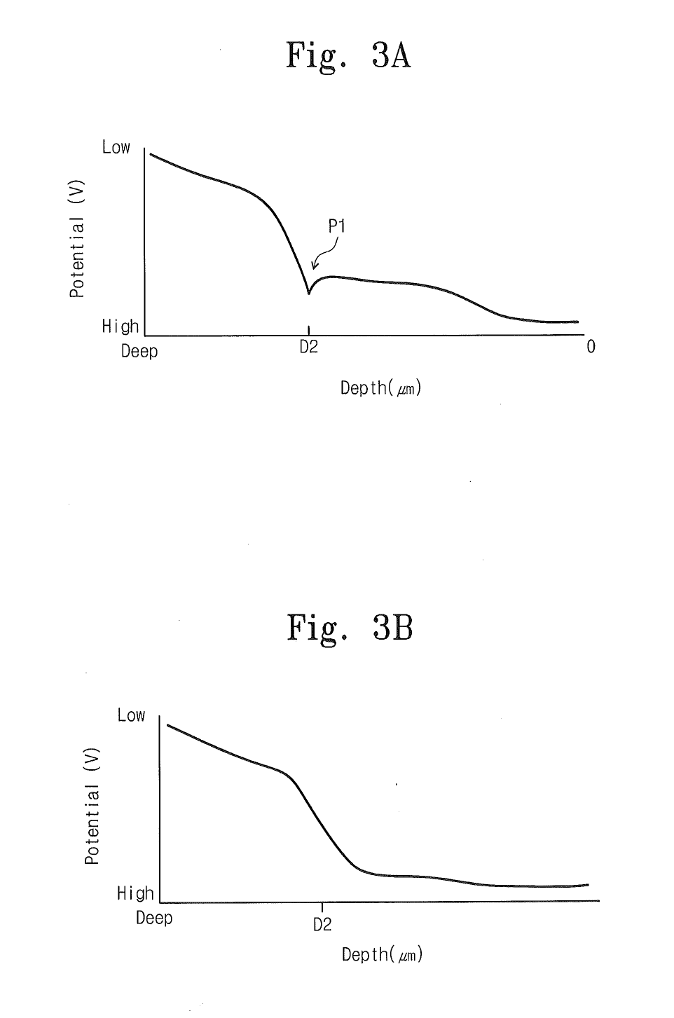

In the case that the number of the second gate pattern is one, to achieve a desired charge transfer capability, the second gate pattern should be configured to have a sufficiently large width. In this case, during the electron transfer process, electrons may remain near the bottom surface of the second gate pattern. As a result, the graph of FIG. 3A has a potential hump P1 that occurs at a depth D2 from the bottom surface of the second gate pattern. By contrast, according to example embodiments of the inventive concept, since the number of the second gate patterns 22 may be two or more and each second gate pattern may have a tapered vertical section, it is possible to suppress electrons from remaining near the bottom surface of the second gate pattern. Accordingly, the potential hump P1 of FIG. 3A does not occur in the graph of FIG. 3B.

Since all of the second gate patterns 22 are provided spaced apart from the device isolation layer 5, all of side surfaces of the second gate patterns 22 can be used as a pathway for transferring electrons. This makes it possible to improve electron transfer capability.

According to the above embodiments, it is possible to increase an electron transfer speed and improve an image lag property. Further, it is possible to increase a full-well capacity of the unit pixel and thereby to improve light sensitivity of the device.

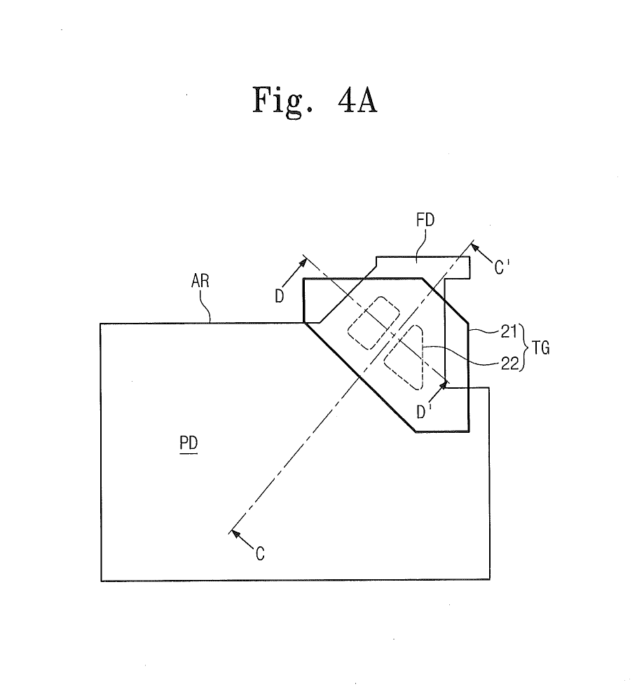

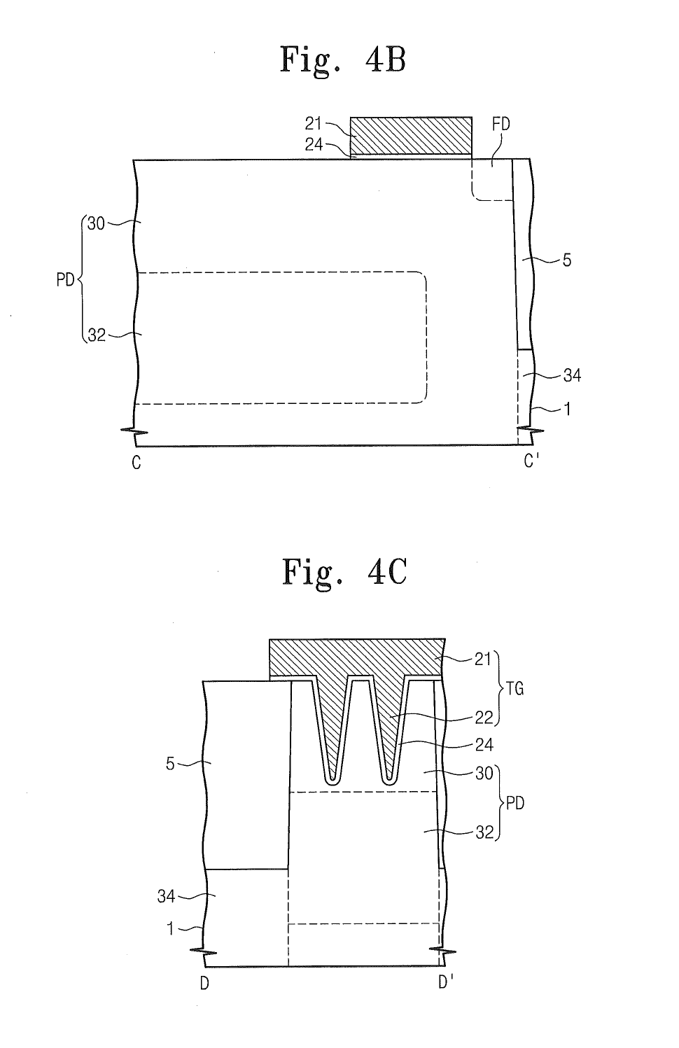

FIG. 4A is a layout diagram of an image sensor according to other example embodiments of the inventive concept. FIGS. 4B and 4C are sectional views taken along lines C-C′ and D-D′, respectively, of FIG. 4A.

Referring to FIGS. 4A through 4C, in the image sensor according to the present embodiments, the active region AR may include a rectangular unit pixel region and a protruding region extending from a corner portion of the unit pixel region. In plan view, the transfer gate TG may be shaped like a triangle. However, each of the second gate patterns 22 may be configured to have one of at least two different planar shapes. The image sensor according to the present embodiments may be configured to have substantially the same features as those of the embodiments previously described with reference to FIGS. 2A through 2D.

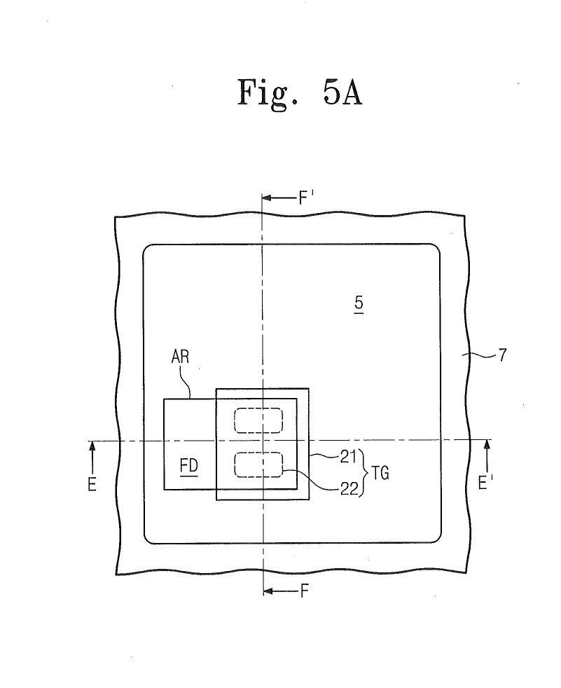

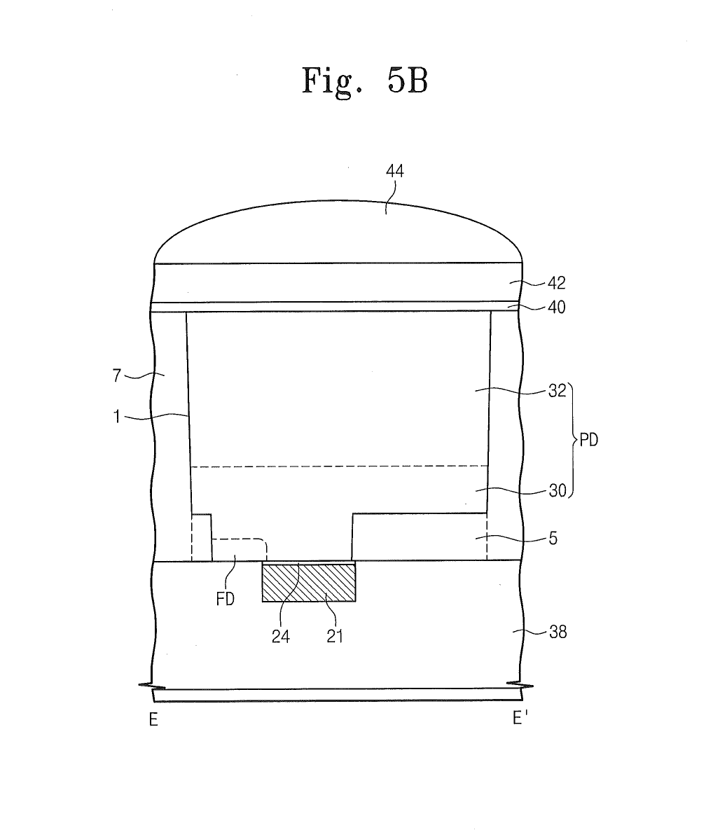

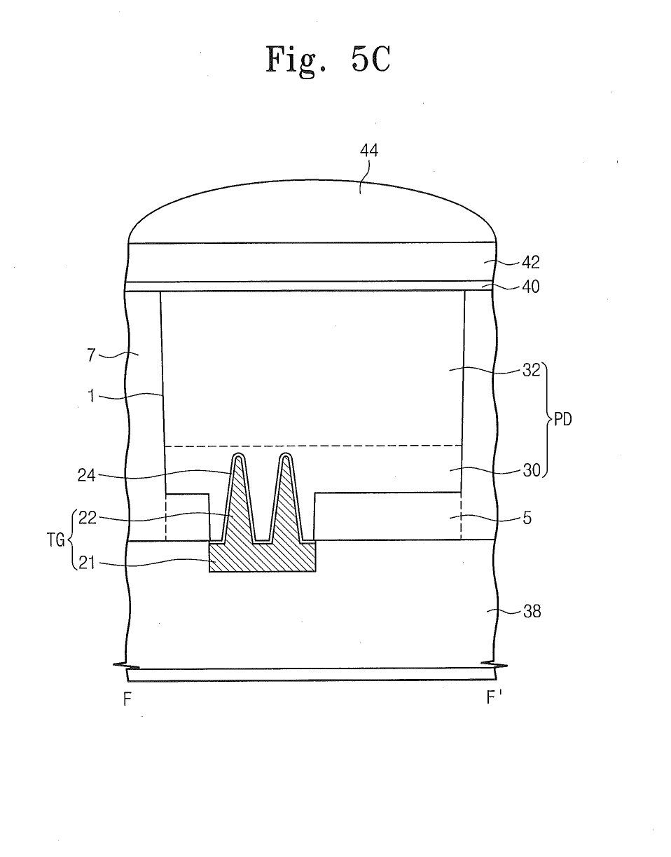

FIG. 5A is a layout diagram of an image sensor according to example embodiments of the inventive concept. FIGS. 5B and 5C are sectional views taken along lines E-E′ and F-F′, respectively, of FIG. 5A.

Referring to FIGS. 5A through 5C, in the image sensor according to the present embodiments, a deep device isolation layer 7 may be provided in the substrate 1 to separate the unit pixel regions from each other. The deep device isolation layer 7 may be provided to penetrate through the substrate 1. The shallow device isolation layer 5 may be provided on a surface of the substrate 1 to delimit the active regions AR. The transfer gate TG and the floating diffusion region FD may be provided on the surface of the substrate 1. The photoelectric conversion portion PD may be formed in the substrate 1. The surface of the substrate 1 may be covered with an interlayer insulating layer 38. An anti-reflecting layer 40, a color filter 42, and a micro lens 44 may be sequentially stacked on other surface of the substrate 1. The image sensor according to the present embodiments may be configured to have substantially the same and/or other features as those of the embodiments previously described with reference to, for example, FIGS. 2A through 2D.

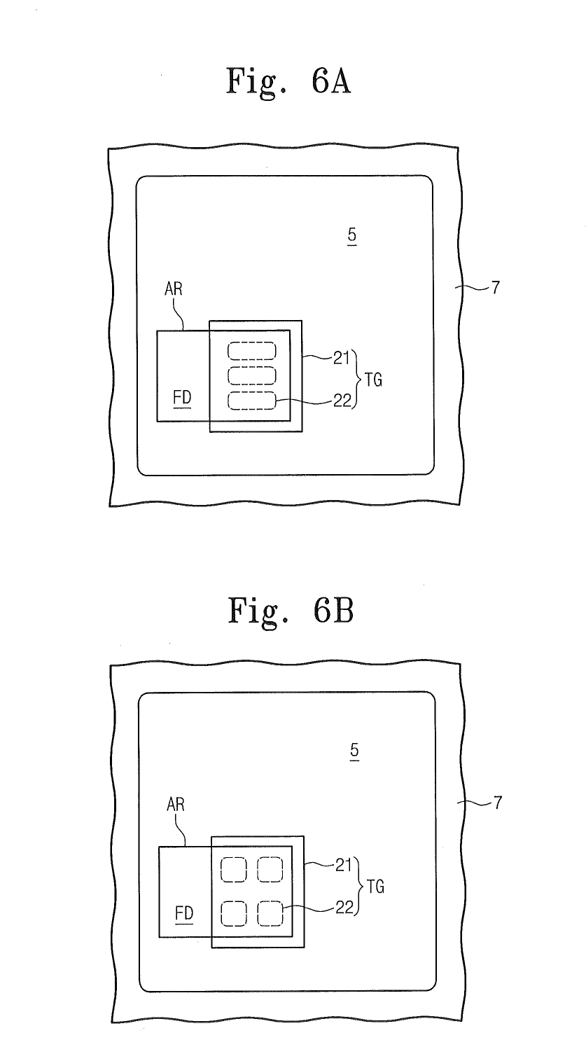

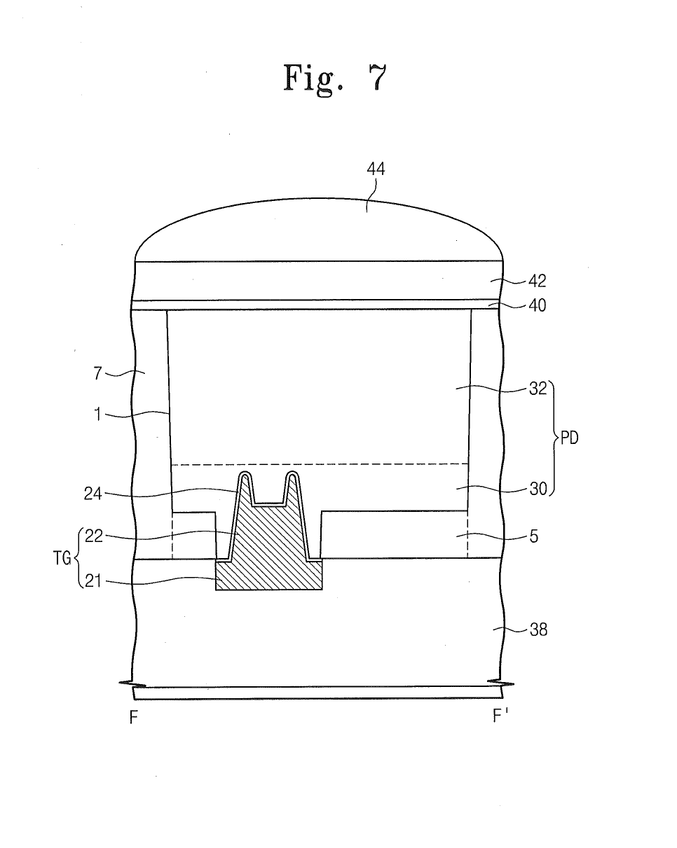

FIGS. 6A and 6B are layout diagrams of image sensors according to even other example embodiments of the inventive concept.

Referring to FIGS. 6A and 6B, in each transfer gate TG, the number of the second gate patterns 22 may be three or four as shown in FIG. 6A or 6B. Alternatively, the number of the second gate patterns 22 may be five or more.

FIG. 7 is a sectional view taken along line F-F′ of FIG. 5A illustrating alternative embodiments according to the inventive concept.

Referring to FIG. 7, a portion of the transfer gate TG positioned between the second gate patterns 22 may have a surface spaced apart from the first gate pattern 21.

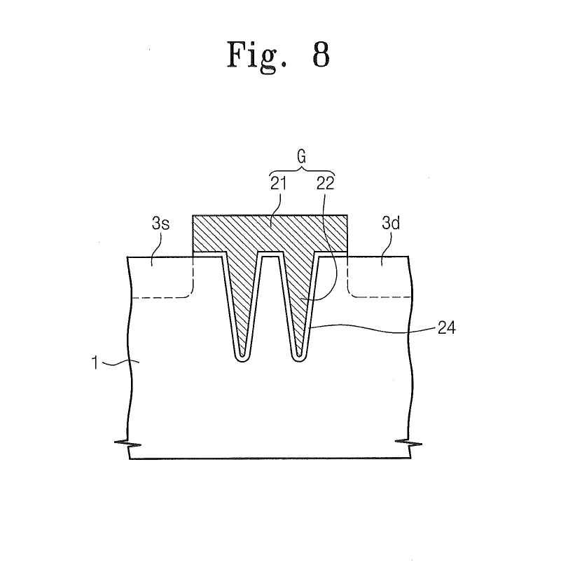

FIG. 8 is a sectional view of a semiconductor device according to yet other example embodiments of the inventive concept.

Referring to FIG. 8, in the image sensor according to the present embodiments, a gate electrode G may be provided on the substrate 1. A source region 3s may be provided in a portion of the substrate 1 at a left side of the gate electrode G, and a drain region 3d may be provided in other portion of the substrate 1 at a right side of the gate electrode G. The gate insulating layer 24 may be interposed between the gate electrode G and the substrate 1. The gate electrode G may include the first gate pattern 21, which may be disposed on the substrate 1, and the second gate patterns 22, which may be connected to the first gate pattern 21 and be extended or inserted into the substrate 1. Due to the presence of the second gate patterns 22, the gate electrode G may have an uneven bottom surface. Accordingly, a distance (i.e., channel length) between the source region 3s and the drain region 3d can be increased, and thus, it is possible to prevent a short channel effect from occurring. The transistor of FIG. 8 may not be limited to the embodiments for the image sensor. For example, it may be applied to realize a variety of semiconductor devices, such as logic or memory chips.

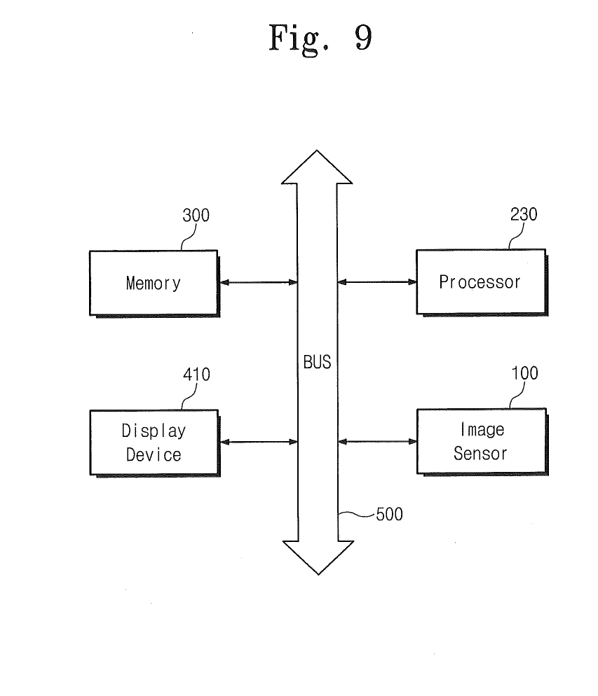

FIG. 9 is a block diagram illustrating an electronic device having an image sensor, according to example embodiments of the inventive concept. The electronic device may be any of various types of devices, such as a digital camera or a mobile device, for example. Referring to FIG. 9, an illustrative digital camera system includes an image sensor 100, a processor 230, a memory 300, a display 410 and a bus 500. As shown in FIG. 9, the image sensor 100 captures an external image under control of the processor 200, and provides the corresponding image data to the processor 230 through the bus 500. The processor 230 may store the image data in the memory 300 through the bus 500. The processor 230 may also output the image data stored in the memory 300, e.g., for display on the display device 410.

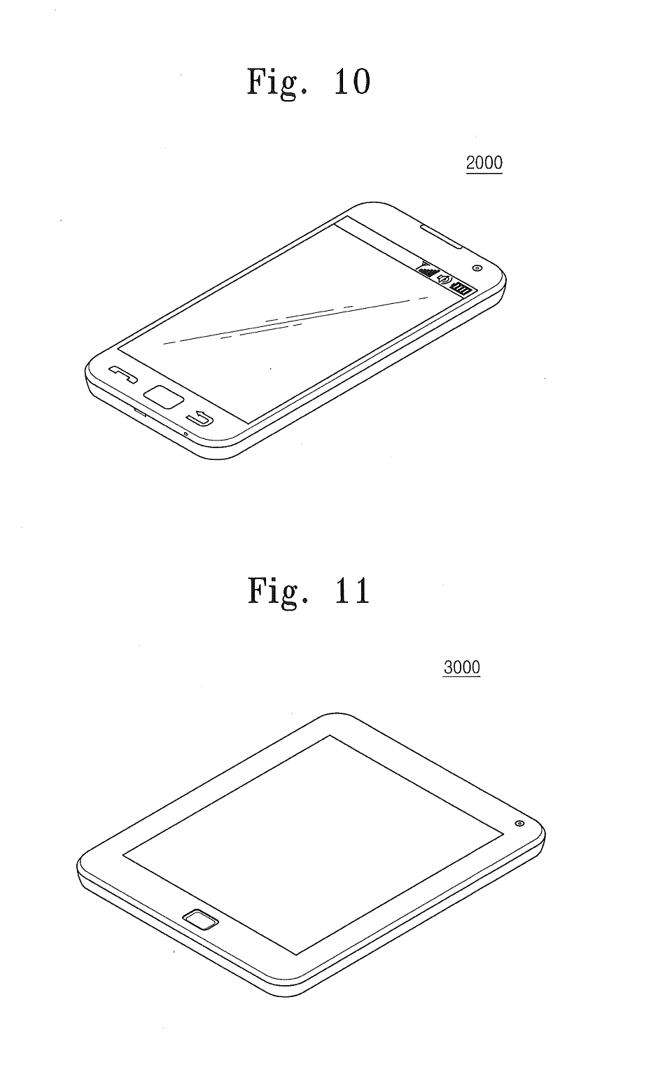

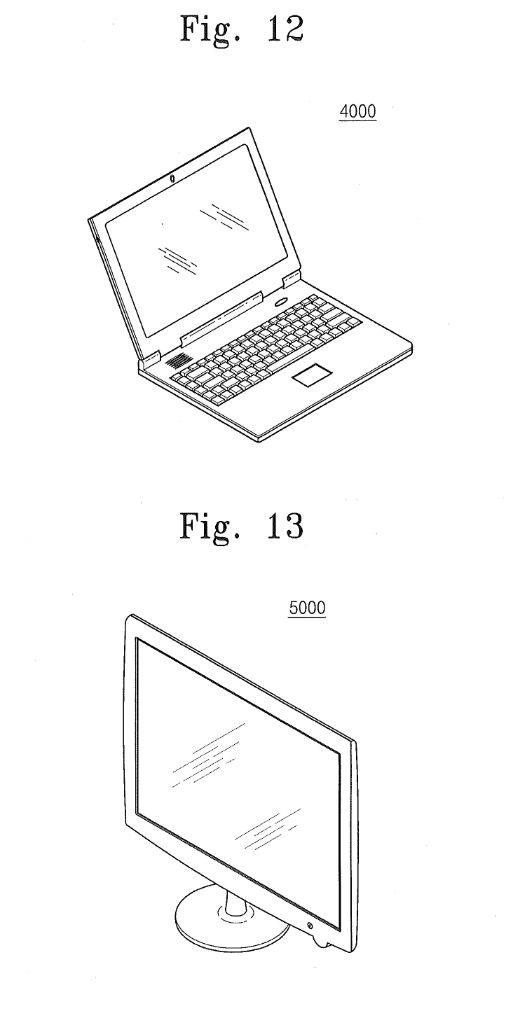

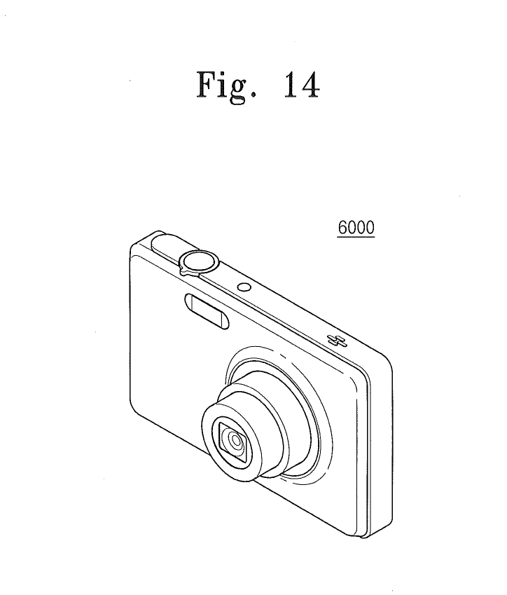

FIGS. 10 through 14 show examples of multimedia devices, to which image sensors according to example embodiments of the inventive concept can be applied. Image sensors according to example embodiments of the inventive concept can be applied to a variety of multimedia devices with an imaging function. For example, image sensors according to example embodiments of the inventive concept may be applied to a mobile phone or a smart phone 2000 as exemplarily shown in FIG. 10, to a tablet PC or a smart tablet PC 3000 as exemplarily shown in FIG. 11, to a laptop computer 4000 as exemplarily shown in FIG. 12, to a television set or a smart television set 5000 as exemplarily shown in FIG. 13, and to a digital camera or a digital camcorder 6000 as exemplarily shown in FIG. 14.

According to example embodiments of the inventive concept, the image sensor may include a transfer gate with a plurality of second gate patterns inserted into a semiconductor substrate. The second gate patterns may have an inclined sidewall, and thus, electric charges of the photoelectric conversion portion can be quickly drifted along sidewalls of the second gate patterns. Accordingly, it is possible to increase an electron transfer speed and improve an image lag property. Further, it is possible to transfer quickly charges with a reduced transfer delay, which may be caused by a potential hump, when compared with the case that the second gate pattern is singly provided. As a result, it is possible to increase a full-well capacity of the unit pixel and thereby to improve light sensitivity of the device.

According to example embodiments of the inventive concept, the semiconductor device may include a gate electrode having an uneven bottom surface. This makes it possible to increase a channel length of a transistor and thereby to prevent a short channel effect from occurring.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate; and
a gate electrode provided on the substrate with a gate insulating layer interposed therebetween,
wherein the gate electrode comprises a first gate pattern disposed on the substrate and a plurality of second gate patterns connected to the first gate pattern and extended into the substrate.

2. The device of claim 1, further comprising a device isolation layer provided on the substrate to delimit an active region,
wherein the second gate patterns are spaced apart from the device isolation layer.

3. The device of claim 1, wherein at least one of the second gate patterns has a width varying depending on a distance from the first gate pattern.

4. The device of claim 3, wherein the width of the at least one of the second gate patterns is greater at a level adjacent to the first gate pattern than at a level distant from the first gate pattern.

5. The device of claim 1, wherein each of the second gate patterns has an inclined sidewall.

6. The device of claim 1, wherein the semiconductor device comprises an image sensor circuit and the gate electrode comprises a transfer gate included in the image sensor circuit,
wherein the semiconductor device further comprises:
a floating diffusion region provided in a portion of the substrate adjacent to a side of the gate electrode; and
a photoelectric conversion portion provided in a lower portion of the substrate at another side of the gate electrode.

7. The device of claim 6, wherein a portion of the substrate between the second gate patterns is adjacent to the floating diffusion region.

8. The device of claim 6, wherein the photoelectric conversion portion further comprises:
a first doped region provided adjacent to the gate electrode; and
a second doped region provided below the first doped region having the same conductivity type as the floating diffusion region,
wherein the second gate patterns are overlapped with the second doped region, in plan view of the image sensor circuit.

9. The device of claim 8, wherein a distance between the second gate pattern and the second doped region less than about 100 μm.

10. The device of claim 1, further comprising:
a first doped region provided adjacent to one of the second gate patterns in the substrate; and
a second doped region provided adjacent to another of the second gate patterns in the substrate.

11. A semiconductor device, comprising:
a substrate; and
a gate electrode provided on the substrate with a gate insulating layer interposed therebetween,
wherein the gate electrode comprises a first gate pattern disposed on the substrate and at least one second gate pattern connected to the first gate pattern and extended into the substrate, and
the second gate pattern has an uneven bottom surface protruding into the substrate.

12. The device of claim 11, wherein a top of a bottom surface of the second gate pattern is located at a level that is equivalent to or lower than a bottom surface of the first gate pattern.

13. An image sensor device, comprising:
device isolation regions in a substrate;
a photoelectric conversion portion in the substrate between the device isolation regions;
a transfer gate of the image sensor device, over and electrically coupled to the photoelectric conversion portion, the transfer gate including at least two protrusions, separated from the device isolation regions, that protrude toward the photoelectric conversion portion.

14. The device of claim 13 wherein the at least two protrusions each have a predetermined tapered width towards the photoelectric conversion portion.

15. The device of claim 14 wherein the tapered width is configured to provide for the formation of a potential gradient from the photoelectric conversion portion to the at least two protrusions in response to the transfer gate being turned on.

16. The device of claim 13 wherein the photoelectric conversion portion comprises an upper doped region and a lower doped region, wherein a spacing between outermost protruding portions of the at least two protrusions and the lower doped region to the outermost protruding portions is less than about 100 μm.

17. The device of claim 13 wherein the photoelectric conversion portion is opposite a lens of the image sensor device.

18. The device of claim 13, further comprising:
a floating diffusion region electrically coupled to the transfer gate.

19. The device of claim 13 wherein the transfer grate further comprises a planar upper portion from which the protruding portions protrude.

20. The device of claim 13 wherein the protruding portions are completely separated from the device isolation regions.
